(19) United States
(12) Patent Application Publication
(10) Pub. No.: US 2025/0201752 A1
(43) Pub. Date: Jun. 19, 2025

(54) SEMICONDUCTOR PACKAGE STRUCTURE AND BYPRODUCT OF SEMICONDUCTOR COMPONENT

(71) Applicant: PANJIT INTERNATIONAL INC., Kaohsiung City (TW)

(72) Inventors: Chung Hsiung HO, Kaohsiung City (TW); Yung-hui WANG, Kaohsiung City (TW); Hung Min LIU, Kaohsiung City (TW)

(73) Assignee: PANJIT INTERNATIONAL INC., Kaohsiung City (TW)

(21) Appl. No.: 18/437,128

(22) Filed: Feb. 8, 2024

(30) Foreign Application Priority Data
Dec. 15, 2023 (TW) 112149092

(51) Int. Cl. H01L 23/00; H01L 23/495

(52) U.S. Cl. CPC H01L 24/29; H01L 24/14; H01L 24/32; H01L 24/48; H01L 24/73; H01L 23/49579; H01L 24/83; H01L 2224/1403; H01L 2224/29082; H01L 2224/29083; H01L 2224/29147; H01L 2224/29166; H01L 2224/32245; H01L 2224/48091; H01L 2224/48245; H01L 2224/48465; H01L 2224/73153; H01L 2224/73265; H01L 2224/83191; H01L 2224/83203; H01L 2224/83447; H01L 2924/10253; H01L 2924/10272

(57) ABSTRACT

A semiconductor package structure and a byproduct of a semiconductor component. The semiconductor package structure including a lead frame, a nanotwinned metal layer, a semiconductor component and a molding layer. The lead frame includes a supporting part and a circuit part. The nanotwinned metal layer is located on the supporting part. The semiconductor component is disposed on the nanotwinned metal layer. The nanotwinned metal layer is located between the supporting part and the semiconductor component. The semiconductor component is electrically connected to the circuit part. The molding layer covers the nanotwinned metal layer and the semiconductor component.

### CROSS-REFERENCE TO RELATED APPLICATIONS

This non-provisional application claims priority under 35 U.S.C. § 119 (a) on Patent Application No(s). 112149092 filed in Taiwan, R.O.C. on Dec. 15, 2023, the entire contents of which are hereby incorporated by reference.

### TECHNICAL FIELD

The disclosure relates to a technical field of semiconductor, more particularly to a semiconductor package structure and a byproduct of a semiconductor component.

### BACKGROUND

In conventional manufacturing process of semiconductors, the improvement of the Chip-to-Wafer bonding and the Wafer-to-Wafer bonding is a significant issue. Recently, in order to realize mass production by improving the bonding means, bonding techniques using a nanotwinned metal become more and more popular due to the advantages of low bonding temperature and short bonding time.

However, current bonding techniques using the nanotwinned metal lacks specific application.

### SUMMARY

The disclosure provides a semiconductor package structure and a byproduct of a semiconductor component, which solve the issue that the bonding techniques using the nanotwinned metal lacks specific application.

One embodiment of this disclosure provides a semiconductor package structure including a lead frame, a nanotwinned metal layer, a semiconductor component and a molding layer. The lead frame includes a supporting part and a circuit part. The nanotwinned metal layer is located on the supporting part. The semiconductor component is disposed on the nanotwinned metal layer. The nanotwinned metal layer is located between the supporting part and the semiconductor component. The semiconductor component is electrically connected to the circuit part. The molding layer covers the nanotwinned metal layer and the semiconductor component.

Another embodiment of this disclosure provides a byproduct of a semiconductor component including a semiconductor layer, an electrical connection layer, a metal layer, a nanotwinned metal layer and a thickened metal layer. The semiconductor layer has a first side and a second side that are opposite to each other. The electrical connection layer is formed on the first side of the semiconductor layer and includes a plurality of micro-bumps. The metal layer is formed on the second side of the semiconductor layer. The nanotwinned metal layer is formed on a side of the metal layer that is opposite to the semiconductor layer. The thickened metal layer is formed on a side of the nanotwinned metal layer that is opposite to the metal layer.

According to the semiconductor package structure and the byproduct of the semiconductor component disclosed by above embodiments, the bonding technique of the nanotwinned metal improves the manufacture of the semiconductor package structure and the semiconductor component.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a schematic view of a semiconductor package structure according to one embodiment of the disclosure;

FIGS. 2 to 5 are schematic views showing a manufacture of the semiconductor package structure in FIG. 1;

FIG. 6 is a schematic view of a byproduct of a semiconductor component according to one embodiment of the disclosure; and

FIGS. 7 to 10 are schematic views showing a manufacture of the byproduct of the semiconductor component in FIG. 6.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

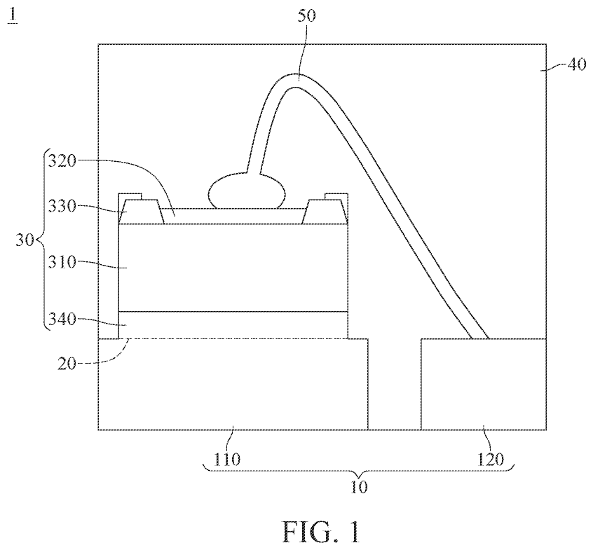

FIG. 1 is a schematic view of a semiconductor package structure 1 according to one embodiment of the disclosure. As shown in FIG. 1, the semiconductor package structure 1 may include a lead frame 10, a nanotwinned metal layer 20, a semiconductor component 30 and a molding layer 40.

The lead frame 10 is, but not limited to being, a metal frame formed by a metal plate. Specifically, the lead frame 10 may be formed by bending or patterning the metal plate. In this embodiment, the lead frame 10 may be made by copper. The lead frame 10 may include a supporting part 110 and a circuit part 120. The supporting part 110 and the circuit part 120 may be connected to or spaced apart from each other.

The nanotwinned metal layer 20 is located on the supporting part 110 of the lead frame 10. The nanotwinned metal layer 20 is, but not limited to being, a nanotwinned copper layer having (111) surface with strong preferred orientation. Thus, most part of the surface of the nanotwinned metal layer 20 may be (111) surface. In this embodiment, the nanotwinned metal layer 20 is not formed on the circuit part 120 of the lead frame 10.

The semiconductor component 30 is disposed on the nanotwinned metal layer 20. The nanotwinned metal layer 20 is located between the supporting part 110 and the semiconductor component 30, and the semiconductor component 30 is electrically connected to the circuit part 120. Further, the semiconductor package structure 1 further includes a lead 50, and the semiconductor component 30 includes a die 310 and a contact 320. The die 310 may be made by a semiconductor component, such as silicon, silicon carbide, III-V group semiconductor element or any other suitable semiconductor materials. The contact 320 is formed on an outer surface of the die 310. In this embodiment, a protective layer 330 is additionally disposed to be formed on a top side of the die 310 and expose the contact 320. The contact 320 and the nanotwinned metal layer 20 are located on two opposite sides of the die 310, respectively. The lead 50 electrically connects the circuit part 120 of the lead frame 10 and the contact 320 of the semiconductor component 30. Specifically, the contact 320 of the semiconductor component 30 is electrically connected to the circuit part 120 of the lead frame 10 via wire bonding.

In this embodiment, the nanotwinned metal layer 20 may be located between two metal layers that are made by the same material as the nanotwinned metal layer 20. Further, in a case that the lead frame 10 is made by copper and the nanotwinned metal layer 20 is a nanotwinned copper layer, the semiconductor component 30 may further include a metal layer 340 that is located below the die 310 and made by copper. The supporting part 110 of the lead frame 10 is bonded to the metal layer 340 via the nanotwinned metal layer 20.

The molding layer 40 covers the nanotwinned metal layer 20 and the semiconductor component 30. The molding layer 40 may include organic composite material, resin composite material, polymer composite material or any other types of solid molding compound. For example, the molding layer 40 may include epoxy. The molding layer 40 of this embodiment covers the nanotwinned metal layer 20, the semiconductor component 30 and the lead 50.

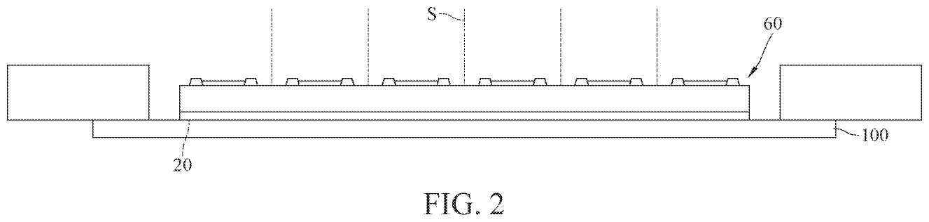

According to one embodiment of the disclosure, the semiconductor package structure 1 shown in FIG. 1 may be formed by Panel-Level Packaging or Wafer-Level Packaging. FIGS. 2 to 5 are schematic views showing a manufacture of the semiconductor package structure 1 in FIG. 1. As shown in FIG. 2, a substrate providing at least one adhesive tape or a substrate whose surface is adhesive is provided as a temporary substrate 100, and a byproduct of the semiconductor package structure 1 is disposed on the temporary substrate 100. The said byproduct may include the nanotwinned metal layer 20 and a component layer 60. The component layer 60 may include at least one metal layer, silicon wafer and at least one metal bump formed on the silicon wafer.

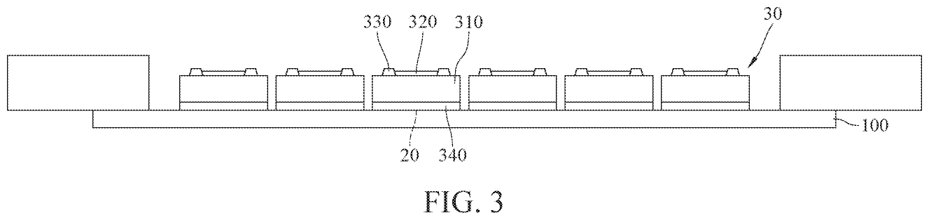

As shown in FIGS. 2 and 3, the byproduct is cut by a cutting machine (not shown) along a predetermined cutting channel S so as to form a plurality of semiconductor components 30. The metal layer of the component layer 60 may function as the metal layer 340 of the semiconductor component 30. The silicon wafer of the component layer 60 may function as the die 310 of the semiconductor component 30. The metal bump of the component layer 60 may function as the contact 320 and/or the protective layer 330 of the semiconductor component 30.

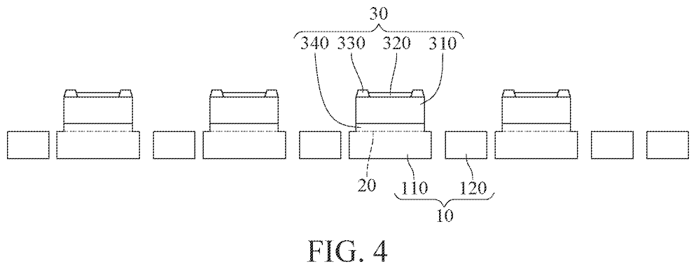

As shown in FIG. 4, the temporary substrate 100 is removed, and the semiconductor component 30 is bonded to the lead frame 10 via the nanotwinned metal layer 20. Further, the nanotwinned metal layer 20 may be provided on at least one of the metal layer 340 of the semiconductor component 30 and the supporting part 110 of the lead frame 10. The above bonding process may be performed by thermocompression bonding. In more detail, the above bonding process may be performed by fast thermocompression bonding or low-temperature thermocompression bonding. Specifically, the bonding process may be completed by performing the thermocompression bonding under 300° C. for 5 to 30 seconds. Alternatively, the bonding process may be completed by performing the thermocompression bonding under 150° C. to 250° C. for 10 to 60 minutes. The disclosure is not limited by the aforementioned bonding temperature and the time cost by the thermocompression bonding.

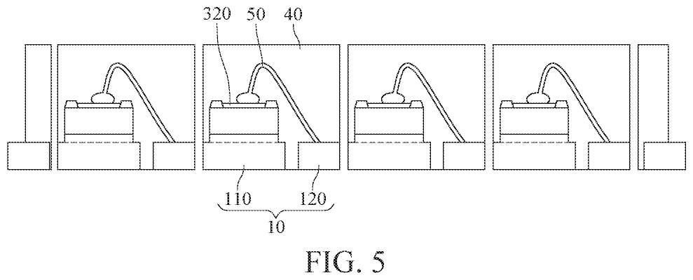

As shown in FIGS. 4 and 5, the lead 50 is provided to electrically connect the contact 320 to the circuit part 120 of the lead frame 10 via wire bonding. Then, the molding layer 40 is formed on the lead frame 10 to cover the nanotwinned metal layer 20, the semiconductor component 30 and the lead 50. The molding layer 40 may be formed by injection molding, thermocompression molding or any other similar means. Finally, multiple semiconductor package structures 1 shown in FIG. 1 may be formed.

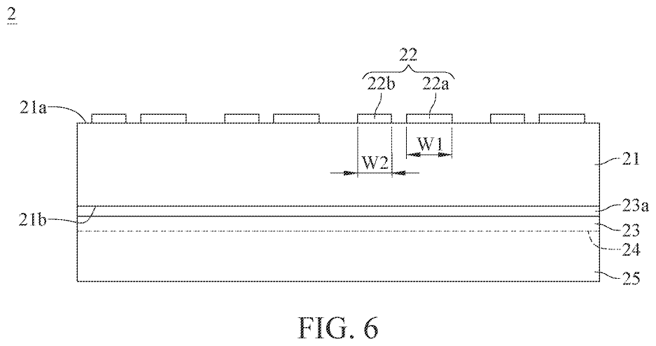

The bonding application of the nanotwinned metal provide by the disclosure is not limited to the embodiment in FIG. 1. FIG. 6 is a schematic view of a byproduct 2 of a semiconductor component according to one embodiment of the disclosure. In this embodiment, the byproduct 2 of the semiconductor component may include a semiconductor layer 21, an electrical connection layer 22, a metal layer 23, a nanotwinned metal layer 24 and a thickened metal layer 25.

The semiconductor layer 21 is, but not limited to being, a silicon wafer having a first side 21a and a second side 21b that are opposite to each other. In this embodiment, the first side 21a and the second side 21b may be a top surface and a bottom surface of the semiconductor layer 21, respectively.

The electrical connection layer 22 is formed on the first side 21a of the semiconductor layer 21. The electrical connection layer 22 includes a plurality of micro-bumps 22a and 22b. The micro-bumps 22a and 22b are arranged on the first side 21a of the semiconductor layer 21 in a staggered manner, and a size of each micro-bump 22a may be different from a size of each micro-bump 22b. As shown in FIG. 6, a width W1 of each micro-bump 22a may be larger than a width W2 of each micro-bump 22b.

The metal layer 23 is formed on the second side 21b of the semiconductor layer 21. The metal layer 23 may be a copper layer located below the semiconductor layer 21.

The nanotwinned metal layer 24 is formed on a side of the metal layer 23 that is opposite to the semiconductor layer 21. Further, the metal layer 23 is located between the semiconductor layer 21 and the nanotwinned metal layer 24. The nanotwinned metal layer 24 is, but not limited to being, a nanotwinned copper layer having (111) surface with strong preferred orientation. Thus, most part of the surface of the nanotwinned metal layer 24 may be (111) surface.

The thickened metal layer 25 is formed on a side of the nanotwinned metal layer 24 that is opposite to the metal layer 23. Further, the nanotwinned metal layer 24 is located between the metal layer 23 and the thickened metal layer 25. In this embodiment, both of the metal layer 23 and the thickened metal layer 25 are made by copper.

In this embodiment, there may be an adhesive metal layer 23a disposed between the metal layer 23 and the semiconductor layer 21. The adhesive metal layer 23a is, but not limited to being, a titanium layer that improves the adhesiveness of the metal layer 23.

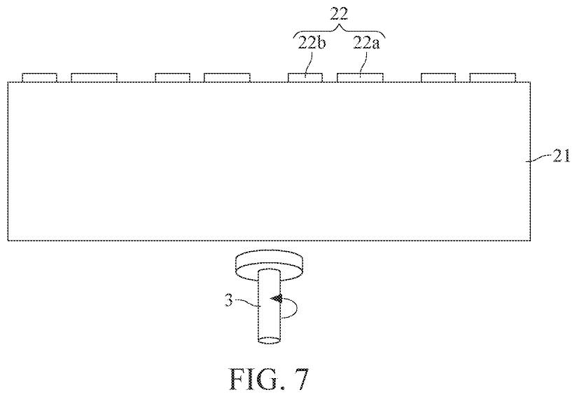

FIGS. 7 to 10 are schematic views showing a manufacture of the byproduct 2 of the semiconductor component in FIG. 6. As shown in FIG. 7, a semiconductor layer 21 where the electrical connection layer 22 is formed is provided, and the semiconductor layer 21 is thinned by a polishing machine 3. Further, the thickness of the semiconductor layer 21 may be reduced by Chemical-Mechanical Polishing.

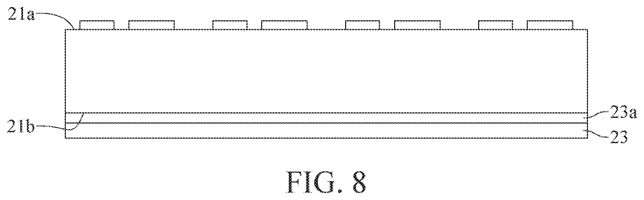

As shown in FIG. 8, the adhesive metal layer 23a and the metal layer 23 are sequentially formed on the second side 21b of the semiconductor layer 21. The adhesive metal layer 23a and the metal layer 23 may be formed by, for example, a deposition process such as sputtering, physical vapor deposition (PVD) or chemical vapor deposition (CVD).

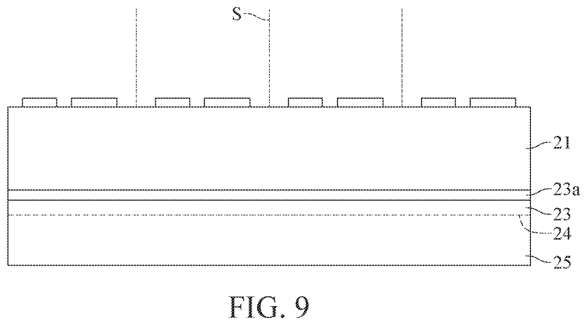

As shown in FIG. 9, the thickened metal layer 25 is bonded to the metal layer 23 via the nanotwinned metal layer 24. Further, the nanotwinned metal layer 24 may be provided on at least one of a surface of the metal layer 23 and a surface of the thickened metal layer 25. The above bonding process may be performed by thermocompression bonding. In more detail, the above bonding process may be performed by fast thermocompression bonding or low-temperature thermocompression bonding. Specifically, the bonding process may be completed by performing the thermocompression bonding under 300° C. for 5 to 30 seconds. Alternatively, the bonding process may be completed by performing the thermocompression bonding under 150° C. to 250° C. for 10 to 60 minutes. The disclosure is not limited by the aforementioned bonding temperature and the time cost by the thermocompression bonding.

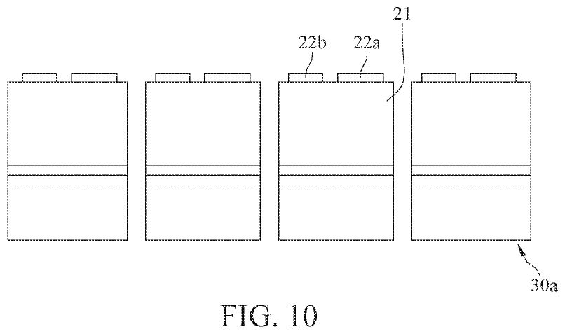

As shown in FIGS. 9 and 10, the byproduct is cut by a cutting machine (not shown) along a predetermined cutting channel S to form multiple semiconductor components 30a. One of the micro-bumps 22a and one of the micro-bumps 22b may function as a contact of any one of the semiconductor components 30a. The semiconductor layer 21 may function as a die of any one of the semiconductor components 30a.

As discussed above, according to the semiconductor package structure and the byproduct of the semiconductor component disclosed by above embodiments, the bonding technique of the nanotwinned metal improves the manufacture of the semiconductor package structure and the semiconductor component.

In a specific application, the nanotwinned metal layer increases the on-resistance (Rds (ON)). As shown by the embodiment in FIG. 1, the nanotwinned metal layer 20 increases the on-resistance between the metal layer 340 of the semiconductor component 30 and the supporting part 110 of the lead frame 10.

In a specific application, the nanotwinned metal layer reduces heterogeneous bonding (bonding between two components of different materials). As shown by the embodiment in FIG. 1, the nanotwinned metal layer 20 prevents the metal layer 340 and the lead frame 10 from being bonded in a heterogeneous manner due to the difference of material and/or microstructure therebetween. As shown by the embodiment in FIG. 6, the nanotwinned metal layer 24 prevents the metal layer 23 and the thickened metal layer 25 from being bonded in a heterogeneous manner due to the difference of material and/or microstructure therebetween.

In a specific application, the nanotwinned metal layer increases the thickness of the metal layer so as to meet the requirements of the product. As shown by the embodiment in FIG. 6, the bonding adopting the nanotwinned metal layer 24 increases the thickness of the metal layer (i.e., increases the overall thickness of the metal layer 23 and the thickened metal layer 25) in a fast and low-cost manner.

In a specific application, the nanotwinned metal layer improves the heat dissipation. As shown by the embodiment in FIG. 6, the bonding adopting the nanotwinned metal layer 24 increases the thickness of the metal layer in a fast and low-cost manner to improve the heat dissipation efficiency thereof.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A semiconductor package structure, comprising:
a lead frame, comprising a supporting part and a circuit part;
a nanotwinned metal layer, located on the supporting part;
a semiconductor component, disposed on the nanotwinned metal layer, wherein the nanotwinned metal layer is located between the supporting part and the semiconductor component, and the semiconductor component is electrically connected to the circuit part; and
a molding layer, covering the nanotwinned metal layer and the semiconductor component.

2. The semiconductor package structure according to claim 1, wherein the semiconductor component comprises a die and a contact, the contact is formed on an outer surface of the die, and the contact and the nanotwinned metal layer are located on two opposite sides of the die, respectively.

3. The semiconductor package structure according to claim 2, further comprises a lead, wherein the lead electrically connects the circuit part of the lead frame and the contact of the semiconductor component.

4. The semiconductor package structure according to claim 1, wherein the nanotwinned metal layer is a nanotwinned copper layer.

5. The semiconductor package structure according to claim 4, wherein the lead frame is made by copper.

6. The semiconductor package structure according to claim 1, wherein the semiconductor package structure is formed by Panel-Level Packaging or Wafer-Level Packaging.

7. A byproduct of a semiconductor component, comprising:
a semiconductor layer, having a first side and a second side that are opposite to each other;
an electrical connection layer, formed on the first side of the semiconductor layer and comprising a plurality of micro-bumps;
a metal layer, formed on the second side of the semiconductor layer;
a nanotwinned metal layer, formed on a side of the metal layer that is opposite to the semiconductor layer; and
a thickened metal layer, formed on a side of the nanotwinned metal layer that is opposite to the metal layer.

8. The byproduct of the semiconductor component according to claim 7, wherein the nanotwinned metal layer is a nanotwinned copper layer, and both of the metal layer and the thickened metal layer are made by copper.

9. The byproduct of the semiconductor component according to claim 7, wherein the plurality of micro-bumps are a plurality of contacts of the semiconductor component.

10. The byproduct of the semiconductor component according to claim 7, wherein a cutting channel is defined between two adjacent ones of the plurality of micro-bumps.
